(19) United States
(12) Patent Application Publication
(10) Pub. No.: US 2019/0320536 A1
(43) Pub. Date: Oct. 17, 2019

(54) PRINTING DEVICE AND PRINTING METHOD FOR APPLYING A VISCOUS OR PASTY MATERIAL

(71) Applicant: Robert Bosch GmbH, Stuttgart (DE)

(72) Inventor: Guenter Gera, Leonberg (DE)

(21) Appl. No.: 16/343,436

(22) PCT Filed: Oct. 6, 2017
(86) PCT No.: PCT/EP2017/075527

§ 371 Date: Apr. 19, 2019

(30) Foreign Application Priority Data
Oct. 21, 2016 (DE) 10 2016 220 678.8

(51) Int. Cl. H05K 3/12; H05K 1/02; H05K 3/34; B23K 1/00

(52) U.S. Cl. CPC H05K 3/1225; H05K 1/0296; H05K 3/3484; B23K 2101/42; H05K 2203/0139; H05K 2203/0121; B23K 1/0008

(57) ABSTRACT

The invention relates to a printing device for applying a viscous or pasty material onto a support substrate and molding a defined material geometry by means of a template. The template which is provided for application and molding purposes has at least one continuous opening, and the opening side facing the support substrate functions as an application opening surface. Furthermore, the opening, in particular the inner wall thereof, forms an outer border for the material geometry outer surface to be molded. As a whole, the template is designed such that an adhesive force of the viscous or pasty material acting on the inner wall of the opening is overcome by means of a relative movement, in particular a movement relative to the support substrate. The template is advantageously formed as a stack composite of at least two sub-templates adjoining each other in a connection region. Each of the sub-templates has at least one sub-opening, by means of which the inner wall of the opening is divided into proportional molding surfaces of the sub-template. Furthermore, sub-opening connection surfaces which correspond to one another are formed in the connection region, and each of the sub-templates can be reversibly separated in the connection region.

### BACKGROUND OF THE INVENTION

The invention relates to a printing device and a printing method for applying a viscous or pasty material, and to a circuit substrate with a printed material deposit.

Modern electronic circuits are increasingly subject to the demands of a very compact construction. More and more electrical and/or electronic components must be interconnected in circuitry in ever tighter spaces, in order to achieve a high degree of miniaturization. As a suitable technology, surface mounting technology (SMT) has established itself over through-hole technology (THT). In this case, so-called SMD components are used, which have solderable bonding surfaces, which are then soldered directly onto a printed circuit board, for example. In order to enable a soldering process, solder paste deposits with a defined paste geometry are applied to bonding pads. Subsequently, the SMD components are mounted into the applied and unfused solder paste deposits via their bonding surfaces. The soldering is finally carried out by means of a subsequent reflow process.

The application of the solder paste is carried out, for example, by screen printing, stencil printing or dispensing. In the stencil printing process, the underside of a plate-like metal stencil with stencil openings is pressed onto a printed circuit board. Then, a solder paste in the form of a pasty solder flux mixture is applied to the top surface of the stencil. Using a blade or squeegee, the solder paste is then spread over the stencil, thereby also pressing it into the stencil openings. By lifting the metal stencil as a whole, the solder paste is released inside the stencil openings and remains as individual solder paste deposits on respective printing sites—the bonding pads of the printed circuit board. This release behavior is influenced by a variety of factors, for example, the stencil opening geometry, the surface composition of the inner wall of the stencil opening, the material properties of the solder paste, etc. Further information can be found in the IPC 7525 Guidelines on Stencil Design. This standard provides a guide to the design and production of suitable stencils intended for the application of solder pastes and assembly adhesives for mounting SMD components. The standard specifies guide criteria, to the effect that a stable process for a solder paste or adhesive application is only possible for an opening ratio (aspect ratio) >1.5 and an area ratio >0.66. The aspect ratio is defined as the ratio of the minimum opening width of the stencil opening that forms the paste geometry to the stencil thickness. The guide criterion for the aspect ratio ensures that when scraping in solder paste, for example, the process by which this is introduced into the opening of the stencil to be filled is reliable. The area ratio in turn specifies the ratio of the projected area of the stencil opening to the peripheral surface (inner wall) of the stencil opening.

The guide criterion for the area ratio ensures a consistent release of the stencil from the material geometry to be printed. The aspect ratio and the area ratio restrict the options for printing very small structures of solder paste or adhesive deposits.

The patent specification DE 102004046629 discloses a method for producing a component. In this case, a printing stencil is used with a lower product layer and an upper grid layer positioned above it. By lifting off the entire printing stencil, the material paste to be printed in the region of the deposited product layer is formed with a different material geometry than in the region of the deposited grid layer. This allows material regions of different thickness to be formed with one printing step. The generally applicable limits with regard to the aspect ratio and the area ratio must continue to be observed.

Patent specification U.S. Pat. No. 4,622,239 discloses an excess pressure blade system. This system comprises a storage chamber containing a solder paste. The solder paste is forced from the storage chamber via a feeder device and inserted into an opening of a printing stencil with excess pressure. The solder paste inserted into the opening is finally leveled off by the blade arranged externally on the storage chamber.

### SUMMARY OF THE INVENTION

The object of the invention is to enable the printing of particularly fine and small structures from a viscous or pasty material by means of stencil printing on a carrier substrate. In particular, the object is directed at improving the area and opening ratios that can be stably printed in the stencil printing process. Also, an object consists of providing circuit substrates with material deposits imprinted by means of stencil printing, which as a connection material enable an electrical contacting of electrical and/or electronic components, in particular SMD components (surface mounted devices), to a conductor structure with a view to a high degree of miniaturization.

The object is achieved by a printing device and a printing method for applying a viscous or pasty material, and by a circuit substrate with a printed material deposit, having the characterizing features of the independent claims.

The starting point is a printing device for applying a viscous or pasty material to a carrier substrate and forming a defined material geometry by means of a stencil.

The stencil designed for the application and forming has at least one continuous opening. The printing device comprises, for example, a support for holding and, additionally, preferably for aligning a carrier substrate to be imprinted. The stencil is placed on the printing surface of the carrier substrate such that its surface is adjacent thereto, for example via its underside. It is preferably held stationary, for example using fixative, for the printing process. One side of the opening facing the carrier substrate then acts as a application opening surface. This corresponds to the printable surface of the viscous or pasty material, which is formed after the application or the printing process and connects to the carrier substrate. In addition, the opening, in particular its inner wall, forms an outer boundary for the outer surface of the material geometry that is to be formed. The stencil is designed overall so as to overcome an adhesive force of the viscous or pasty material acting on the inner wall of the opening by means of a relative movement, in particular a movement relative to the carrier substrate. The relative movement is achieved, for example, by means of a positioning device which is brought into operative connection with the stencil. The stencil is advantageously formed as a stack composite of at least two sub-stencils that adjoin each other in a connection region. The sub-stencils have at least one partial opening each, by means of which the inner wall of the opening is divided into proportional shaping areas of the sub-stencils. In addition, mutually corresponding connecting faces of the partial openings are formed in the connection region. In addition, the sub-stencils are each reversibly separable from each other in the connection region.

This enables the stencil-based shaping of the outer surface of the defined material geometry by temporally staggered partial demolding operations using the sub-stencils. In comparison to the otherwise known demolding of the outer surface of the material geometry using only a single stencil, in relation to the respective sub-stencil, overall in contrast this produces a significantly improved release behavior of the viscous or pasty material. This is obtained by an adhesion force to be overcome now being reduced as a result of the proportional shaping surface. Another advantage obtained is due to the fact that by this method, material geometries with reduced printing area can be formed on a carrier substrate, which previously could not be printed by a stencil printing process. The limitation of the printability was due, for example, to a detachment of the printed material on the printing surface when the stencil is lifted off. The detachment occurs due to the excessive adhesive forces of the material to be printed acting on the inner wall of the stencil opening. Furthermore, a required printing height of the defined material geometry is now advantageously obtained cumulatively from the partial demolding operations of the sub-stencils over their respective stencil thickness. The absolute minimum opening width within a sub-stencil can therefore be reduced to a dimension corresponding to the stencil thickness. In this way, by providing the sub-stencils, as a result finer and smaller structures can be printed using a stencil printing process and thus, for instance in the field of electronic assembly production, a connection technology for implementing a high level of miniaturization can be provided which is particularly suited to series production.

An additional improvement results from an extension of the printing device and occurs when for the stencil an overall area ratio as the ratio of the area of the inner wall to the application opening surface is <0.66. A demolding of the material geometry to be printed as a whole is also enabled, namely by this being partially demolded in a temporally staggered manner using sub-stencils. The overall area ratio can in principle be chosen arbitrarily small by increasing the number of sub-stencils and ensuring a release behavior of a respective sub-stencil. Small structures can be printed particularly economically and in a stable manner with an overall area ratio in particular between 0.3 and 0.5 and/or with 2 to 5 sub-stencils.

A further advantage is obtained if for a sub-stencil, a part-related area ratio as the ratio of the shaping area of the partial opening to the associated connection area facing the carrier substrate or to the application opening area is >=0.66, in particular between 0.66 and 2. This means that the release behavior of the sub-stencil can be ensured. The existing limits of an area ratio applicable to stencil printing are therefore shifted to the level of a sub-stencil. In general, it is possible to provide a sub-stencil with a minimum stencil thickness of 10 in particular for printing solder paste deposits. At least one, a plurality of or preferably all sub-stencils of the stack composite have an individual stencil thickness within a range from 10 μm-150 μm, preferably between 40 μm and 120 μm.

A simple design of the printing device comprises a standard blade, by means of which the viscous or pasty material is pressed into the opening of the stencil by purely mechanical means by being spread over the stencil. In order to carry out this process consistently, the stencil has an overall aspect ratio as the ratio of the smallest opening width of the opening to the stencil thickness of the stencil of >1.5. The stencil thickness of the stencil is given by the sum of the stencil thicknesses of all sub-stencils contained in the stack composite.

An improved extended design is obtained if the printing device comprises a closed excess pressure blade for applying the viscous or pasty material into the at least one continuous opening of the stencil. This closed excess pressure blade is formed, for example, by a printing head, which rests on the stencil and completely covers an entry opening surface of the stencil facing away from the carrier substrate, and which is designed to introduce the viscous or pasty material into the opening under pressure. Advantageously, the stencil can now also have an overall aspect ratio of <1.5. Thus, even the smallest stably printable material geometries can be implemented, in particular including those for which an ever-decreasing overall area ratio of less than 0.6 is required for the stencil. Small, structures can be printed stably and particularly economically at an overall aspect ratio of 0.6 to 1.0.

The following table summarizes the printing options based on the example of a cylindrical solder paste deposit to be printed with a diameter d and a printing height h.

The various columns are labeled as follows:
Column I: specific characteristic values, in particular a printing geometry as a circle or consideration of the printing geometry for an exemplary component type
Column II: the diameter of the circle in μm
Column III: the thickness of a sub-stencil of the stack composite in μm
Column IV: the number of sub-stencils of equal thickness in the stack composite
Column V: the total height of the stack composite formed from the number of sub-stencils of the same thickness in μm
Column VI: the resulting area ratio per sub-stencil
Column VII: the resulting overall aspect ratio for the stack composite.

| | | | | | | VI | |
|---|---|---|---|---|---|---|---|
| | | | III | | V | Area | |
| | | | Thickness | IV | Height | ratio | VII |
| | I | II | of sub- | Number of | of | per | Overall |
| | Characteristic | Diameter | stencil | sub-stencils | stack | sub- | aspect |
| | values | in μm | in μm | in stack | in μm | stencil | ratio |
| A1 | Circle | 27 | 10 | 1 | 10 | 0.68 | 2.7 |
| A2 | Circle | 27 | 10 | 2 | 20 | 0.68 | 1.4 |
| A3 | Circle | 27 | 10 | 3 | 30 | 0.68 | 0.9 |
| A4 | Circle | 45 | 10 | 3 | 30 | 1.13 | 1.5 |
| B1 | Circle | 400 | 150 | 1 | 150 | 0.67 | 2.7 |
| B2 | Circle | 330 | 125 | 1 | 125 | 0.66 | 2.6 |
| B3 | Circle | 265 | 100 | 1 | 100 | 0.66 | 2.7 |
| B4 | Circle | 200 | 75 | 1 | 75 | 0.67 | 2.7 |
| C1 | Circle | 400 | 150 | 2 | 300 | 0.67 | 1.3 |
| C2 | Circle | 330 | 125 | 2 | 250 | 0.66 | 1.3 |
| C3 | Circle | 265 | 100 | 2 | 200 | 0.66 | 1.3 |
| C4 | Circle | 200 | 75 | 2 | 150 | 0.67 | 1.3 |
| D1 | BGA08 | 400 | 150 | 1 | 150 | 0.67 | 2.7 |
| D2 | BGA05 | 300 | 75 | 2 | 150 | 1 | 2 |
| D3 | BGA04 | 250 | 75 | 2 | 150 | 0.83 | 1.7 |
| D4 | 200 μm bump | 200 | 75 | 2 | 150 | 0.67 | 1.3 |
| D5 | BGA03 | 150 | 50 | 3 | 150 | 0.75 | 1 |

The preferred values are a circle of diameter 27 μm to 400 μm, a sub-stencil thickness of 10 μm-150 μm, a number of sub-stencils from 1 to 3 and/or a total printing height of the solder paste deposit of 10 μm to 300 μm.

The lines A1 to A4 show exemplary embodiments which indicate the limits of the printing capability for the smallest printing geometries.

Lines B1 to B4 show limits of known printing techniques using only one stencil for larger circle diameters, using the example of a small circular diameter in accordance with the design in line A1.

In comparison to the designs given in B1 to B4, the designs in C1 to C4 show the possible print geometry that achieves increased printing heights for the same circular diameter and with the use of two sub-stencils of equal thickness.

The lines D1 to D5 show the application of a printing geometry for a constant printing height of 150 μm and similar circular diameters as in the versions in lines B1 to B4, or C1 to C4, for specific component types with different numbers of sub-stencils and their thicknesses.

Essentially, the analysis within the above summary table suggests a minimum part-related area ratio of 0.66 and the use of at least two sub-stencils within a stack composite. Exemplary embodiments with overall aspect ratios of only marginally below 1.5 may remain viable under optimized process conditions, even if a purely mechanical blade is used. This can also be ensured, in principle, by the use of a closed excess pressure blade. The analysis can be extended in the same way with regard to the provision of other printing geometries, in particular square, rectangular, oval geometries or derivatives of these. This also applies to designs with a part-related area ratio of >0.66, the provision of more than 3 sub-stencils and/or different sub-stencil thicknesses within a stack composite. In a very simple way, this allows printing geometries to be implemented that are not feasible using the known printing techniques.

In a particularly advantageous embodiment of the printing device, the partial openings of at least two sub-stencils in the stack composite that form the at least one opening are designed differently in their respective geometry and/or size. This offers the possibility of implementing a plurality of different printable material geometries. In particular, such material geometries can also be implemented, in which different cross-sectional areas and shapes merge into each other across different cutting planes, in particular as stepped geometries. In order to make the production of sub-stencils particularly simple and cost-effective, it is advantageous to provide the partial opening of a sub-stencil with a constant cross-sectional area and/or shape across the stencil thickness. The number of cutting planes between different cross-sectional areas and shapes of a defined material geometry therefore defines the necessary connection planes of a minimum number of sub-stencils in the simplest way. Alternatively or additionally, at least two partial openings of a sub-stencil can also differ in their respective geometry and/or size. This results in greater flexibility in the implementation of any desired printed pattern of material geometries spaced apart from each other on a carrier substrate using stencil printing. In principle, the cross section of a partial opening can have a circular, oval or rectangular cross section. These cross sections can be produced particularly simply, for example using a stamping or laser cutting process.

In certain embodiments, the stencil thickness of each of the at least two sub-stencils arranged in the stack composite is different. In this way, different requirements can be taken into account in relation to a sub-stencil, for example obtaining an advantageous part-related area ratio, a simple production in the case of abrupt changes in cross-section within the material geometry to be manufactured, et cetera.

Further advantageous embodiments of the printing device allow for the stencil having a plurality of openings, particularly in a pattern arrangement. The pattern arrangement is obtained, for example, from a connection diagram of an electrical and/or electronic component, in particular an SMD component, which requires printed solder paste or adhesive deposits on a printed circuit board that correspond to the connection diagram. The center-to-center distance (pitch) of two immediately adjacent openings is <=2 mm, in particular in a range between 0.1 mm and 1.0 mm. For the determination of the center-to-center distance, points or axes of symmetry of the respective openings and their smallest distance apart from each other are determined. A very simple determination is obtained in the case of an overall symmetrical pattern arrangement itself and/or with identical openings. So-called pitch specifications are generally known in electronics manufacturing. In a particularly advantageous arrangement, a minimum material bridge between two adjacent partial openings of a sub-stencil remains >=the stencil thickness of the sub-stencil.

It is generally advantageous if at least one of the sub-stencils, preferably all sub-stencils arranged within the stack composite, are designed, for example, as a metal stencil, preferably made of stainless steel, and/or as a sheet metal stencil. In the sheet metal stencil design, the connection region of two adjacent sub-stencils within the stack composite, as well as preferably the contact surface of the sub-stencil adjoining the carrier substrate, are situated within a respective plane. It is also preferable that the contact surface and all connection regions contained within the stack composite are arranged parallel to each other. In addition, a demolding direction of at least one of the sub-stencils, preferably all sub-stencils, is oriented perpendicular to the designated print area on the carrier substrate.

It is further preferable that the printing device, in particular the sub-stencils, comprises at least one alignment element for the defined arrangement of the sub-stencils. This ensures that the stack composite containing the sub-stencils accurately replicates the shape of the material geometry to be printed. One possibility in this case is to provide the sub-stencil with registration marks, for example, which enable a reference orientation of the sub-stencils relative to each other. This can also be detected by means of an optical system, in particular a camera system, and specify a positional correction for individual sub-stencils. Alternatively or in addition, stop pins can be provided for the mechanical alignment of the sub-stencils. In addition, the printing device preferably comprises at least one positioning device for executing a relative movement of at least one sub-stencil within the stack composite. In particular, the positioning device is designed so as to separate sub-stencils from one another and to enable a partial demolding of the outer surface of the material geometry of a respective sub-stencil. In particular, the separation of the sub-stencils is carried out in a synchronized way temporally and/or in a separation sequence, which will also become clearer in the subsequent description of the printing method. More advantageously, the printing device also comprises at least one guide element for the guided change of position of at least one sub-stencil, for example during the positional correction and/or during the relative movement for a partial demolding. A guiding function can also be performed by the positioning device in at least one or two or three spatial directions.

Particularly suitable materials as printable viscous or pasty materials are those which, after the application of the material and the molding of a defined material geometry, are able to maintain this geometry largely unchanged, at least until the time of any subsequent processing stage, as a result of their rheological material properties. For an engineering application, in particular for electrical and/or mechanical contacting within an electrical assembly, for example known solder pastes or conductive adhesives already used for stencil printing are suitable, as are heat-conducting pastes or conductive pastes. Equally possible are solder resist lacquers or elastic materials, such as silicones, for forming vibration-damping buffer elements or structures, in particular for vibration-sensitive sensors. Further processing can take the form of a drying process or a physical or chemical curing process, for example. This can be carried out without affecting the molded material geometry, for example the formation of a defined resist lacquer geometry or vibration buffer geometry. In contrast, in a component placement process, for example to produce an electrical and/or mechanical connection of the printed material to an electrical and/or electronic component, in particular in conjunction with an additional tempering process, such as a reflow soldering process, the originally molded material geometry is largely or at least partly lost. The molded material geometry comprises at least a defined shape and size.

Particularly advantageously, the printing device is designed as a solder paste printing device with a solder paste stencil for receiving a solder paste, or the printing device is designed as an adhesive printing device with an adhesive stencil for receiving an adhesive. In addition, guidelines for the design and manufacture of these stencils can be found in the above-mentioned IPC standard 7525.

The invention also leads to a printing method for applying a viscous or pasty material to a carrier substrate and forming a defined material geometry by means of a stencil. Such a printing method can be carried out, for example, by one of the previously described embodiments of a printing device according to the invention. As a minimum, the stencil has at least one continuous opening with an application opening surface facing the carrier substrate. In addition, the inner wall of the opening forms an outer boundary for the outer surface of the material geometry which is to be formed. A particular advantage is obtained in particular by the fact that a maximum shaping area of the stencil is determined for a circumferential outer surface section of the material geometry, for which in the event of a relative movement of the stencil, in particular with respect to the carrier substrate, an adhesion of the viscous or pasty material to the shaping area can still be overcome. It is further provided that at staggered intervals, the removal of at least two outer surface sections of the material geometry from the mold is begun, in each case having a surface area up to the size of the specified shaping area, using the stencil. In this way, it is possible to construct a material geometry which has previously not been printable in a stable manner with stencil printing, by using a specific and coordinated sequence of partial demolding processes. This applies in particular to the printing of extremely fine and small printed structures, in particular comprising a solder-paste or adhesive deposit. A simple determination of the maximum shaping area can be carried out for solder-paste or adhesive printing, for example, by application of the specifications for an area ratio in accordance with the IPC standard 7525 to a sub-stencil which is to be determined. An even more accurate method, taking into account all influencing factors, can be determined in an experiment in real conditions. This involves, for a given print material and the material geometry to be printed, gradually modifying a print stencil until a stable removal of the print material corresponding to an outer surface section is possible. A stack composite, for example, of sub-stencils placed on top of one another is provided, wherein each of the sub-stencils has a proportional shaping area for the defined material geometry. The proportional shaping area can be designed to have a value up to the specified maximum shaping area. By separation and guided lifting of one of the sub-stencils from the stack composite, a partial demolding of a specific outer surface section is then carried out. The separation from the stack composite is preferably carried out in accordance with the arrangement sequence of the sub-stencils within the stack composite. Accordingly, the sub-stencil in the stack composite which is located furthest away from the carrier substrate is the first to be separated from the stack composite. This is followed by lifting and separating the next adjacent sub-stencil in each case to the last separated sub-stencil. The first sub-stencil resting directly on the carrier substrate is therefore the last to be removed from the carrier substrate. The formation of the stack composite in preparation for a printing process is then carried out in the reverse order by an appropriate placement of the sub-stencils.

A particular embodiment provides that at least one of the outer surface sections having an area up to the size of the specified maximum shaping area is completely demolded before the removal of at least one other outer surface section is begun. In this way, a very stable process management can be applied, because only one sub-stencil is actively printed at any given time in the printing process.

An alternative embodiment of the printing method differs in that, after one sub-region of at least one outer surface section has already been removed from the mold, at least one other outer surface region is then removed from the mold at the same time. The simultaneous demolding is carried out in such a way that at any subsequent time a surface area of the remaining areas of these outer surface sections yet to be demolded is present, which is smaller than the specified maximum shaping area. This results in the advantage of a time-optimized and fast printing speed.

A particularly good result is achieved when the viscous or pasty material is formed as a material deposit on a bonding pad of a printed circuit board, a DBC, an LTCC, an IMC, a wafer or a solar cell with the defined material geometry. This allows a very flexible electronics production with very fine, small printing structures to be implemented cost-effectively as part of a series production. This includes a solder paste, a thermal conducting paste, a conductive paste or a conductive adhesive being printed on the carrier substrate, and in particular on the one described above, as the viscous or pasty material.

The invention also leads to a circuit substrate having at least one material deposit with a defined material geometry applied by means of stencil printing. The circuit substrate comprises at least one track structure, and after the printing of material deposits for electrical contacting to the track structure it can be populated with at least one electrical and/or electronic component. Such a circuit substrate may be produced, in particular, with one of the previously described embodiments of a printing method according to the invention and/or with one of the previously described embodiments of a printing device according to the invention. The improvement is particularly evident in the fact that the at least one imprinted material deposit, in particular a solder-paste or adhesive deposit, has a printable surface connecting to the carrier substrate and the material geometry has an outer surface shaped by means of an inner wall of an opening of the printing stencil, wherein a ratio of the outer area to the printable area is <0.66. Small printing structures designed in this way enable the implementation of a high degree of miniaturization.

An advantageous facility is obtained if the printed material deposit has different cross-sectional areas and/or shapes in cutting planes parallel to the printable surface. This allows a wide range of applications to be covered by a flexible representation of widely varying material geometries of a required material deposit.

In addition, advantages are obtained in the case of a circuit substrate with a plurality of material deposits in the form of a pattern arrangement. The pattern arrangement is implemented, for example, to correspond to a connection diagram of an electrical and/or electronic component, in particular an SMD component. In this way, electrical and/or electronic components with a very small pitch, in particular a pitch between 0.1 mm and 1.0 mm, can be advantageously materially bonded to a printed circuit board, a DBC, an LTCC, an IMC, a wafer or a solar cell, for example, as the circuit substrate, for example by soldering or gluing.

### BRIEF DESCRIPTION OF THE DRAWINGS

Further advantages, features and details of the invention can be found in the following description of preferred exemplary embodiments and from the drawings. These show:

FIG. 1a) through FIG. 1e): an exemplary embodiment of a printing device for applying a viscous or pasty material to a printed circuit board with a temporal sequence during a printing process,

FIG. 2: a detail of the printing stencil in a molding region for a printable material geometry,

FIG. 3a) through 3d): different designs of a stack composite of sub-stencils,

FIG. 4: an alternative method to that of FIG. 1a)-1e) for introducing the viscous or pasty material into the opening of a stencil by means of an excess pressure blade.

### DETAILED DESCRIPTION

In the figures, functionally identical components are each labeled with the same reference numeral.

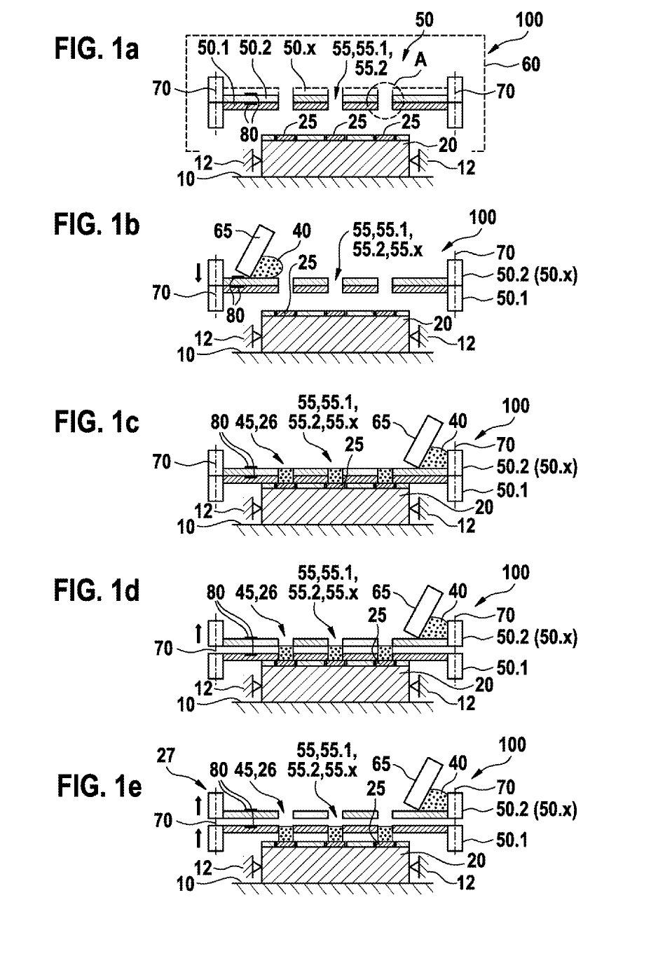

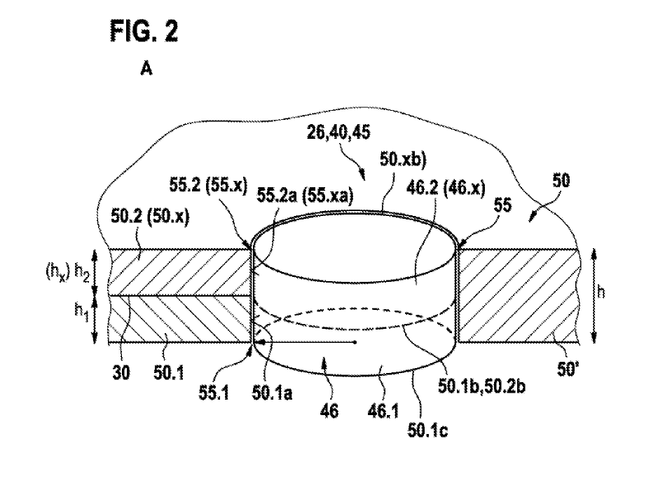

FIG. 1a) shows an example of an embodiment of a printing device 100 for applying a viscous or pasty material at a time prior to the execution of a printing process. The printing device 100 comprises at least one support 10 for holding a carrier substrate 20 to be imprinted, in particular a circuit substrate. The carrier substrate 20 is, for example, a printed circuit board, a DBC, an LTCC, an IMC, a wafer or a solar cell. The carrier substrate 20 rests with its underside on the support 10. The carrier substrate 20 is preferably aligned by means of an alignment and/or fixing unit 12 within the printing device 100 with a defined orientation and/or fixed onto the bearing 10 in a stationary manner. On a top side of the carrier substrate 20, at least one bonding pad 25 is formed for electrically contacting to an electrical and/or electronic component. Using a stencil printing process, a material deposit 26 with a defined material geometry 45 will then be printed on at least one bonding pad 25. For this purpose, a novel type of printing stencil is provided in the form of a stack composite 50 composed of a plurality of sub-stencils 50.1, 50.2, 50.x. The stack composite 50 comprises at least two sub-stencils 50.1, 50.2, although more sub-stencils 50.x can be included as required. FIG. 2 shows an enlargement of a detail A of the printing stencil 50 in a molding region, for example a cylindrical material deposit 26, for a printable material geometry 45. The material geometry 45 has an outer surface 46 to be shaped in a defined way. Conventionally, the outer surface 46 would be shaped by means of a continuous opening 55 formed in a single stencil 50′ (shown schematically in the right-hand side view). The inner wall of the opening 55 forms an outer boundary for the outer surface 46 of the material geometry 45 to be shaped over a printing height h. The side of the opening 55 facing the carrier substrate 20 thereby acts as an application opening surface 50.1c. This matches the subsequent printable surface on the carrier substrate 20. The left-hand side view shows a schematic representation of the design of the novel printing stencils as a stack composite 50 of at least two sub-stencils 50.1, 50.2, 50.x that adjoin each other in a connection region 30. The sub-stencils 50.1, 50.2. 50.x are each designed with a stencil thickness h1, h2, hx and each have at least one partial opening 55.1, 55.2, 55.x, through which the inner wall of the opening 55 is divided into proportional shaping areas 50.1a, 50.2a, 50.xa of the sub-stencils 50.1, 50.2, 50.x. In addition, in the connection region 30 mutually corresponding connecting surfaces 50.1b, 50.2b, 50.xb of the partial openings 50.1, 50.2, 50.x are formed, over which the print material 40 which is introduced into each of the partial openings 55.1, 55.2, 55.x is seamlessly merged. Via the proportional shaping areas 50.1a, 50.2a, 50.xa, corresponding outer surface sections 46.1, 46.2, 46.x are partially demolded at delayed intervals relative to each other. Overall, the design as a stack composite 50 allows a reduced overall area ratio.

FIGS. 1b) to 1e) show the execution of a printing process, wherein for the sake of clarity a further sub-stencil 50.x has not been shown. From FIG. 1b) it is evident that a viscous or pasty material 40, in this example a solder paste or a conductive adhesive, is provided via an application device 65 for printing onto the bonding pads 25. The application device 65 comprises, for example, a blade, by means of which the solder paste or conductive adhesive 40—as shown in FIG. 1c)—is spread over the surface of the outermost sub-stencil 50.2 or 50.x. In the spreading process, the solder paste or conductive adhesive 40 is mechanically pressed into the openings 55 of the stack composite 50. In the process, all partial openings 55.1, 55.2, 55.x are filled with the solder paste or conductive adhesive 40. In accordance with FIG. 1d), in a subsequent production step the outermost sub-stencil 50.2 or 50.x is separated from the stack composite 50 and lifted up until at least one shaping area 50.2a or 50.xa associated with the raised sub-stencil 50.2 or 50.x has fully removed a corresponding outer surface section 46.2 or 46.x of the material geometry 45 from the mold. Thereafter, at staggered intervals a further partial demolding of an adjacent outer surface section 46.1 is completed by separating and lifting the following sub-stencil 50.1 in the remaining stack composite 50. FIG. 1e) shows the lifting of the final sub-stencil 50.1 resting on the carrier substrate 20, which completes the entire demolding of the whole material geometry 45 and the printing process as such is then completed. Alternatively, it can be provided that after only one sub-region of at least one outer surface region has already been removed from the mold by an associated sub-stencil, at least one other adjacent outer surface region is removed from the mold by the following sub-stencil at the same time. In doing so, care must be taken to ensure that the simultaneous demolding is implemented in such a way that at any subsequent time, a surface area of the remaining areas of these outer surface sections yet to be removed from the mold is less than a maximum shaping area that is still permissible by a limiting area ratio in relation to the sub-stencils proportionally involved in the subsequent removal from the mold. In principle, the separation and lifting of the sub-stencils 50.1, 50.2, 50.x is carried out by the positioning device 60 relative to the carrier substrate 20 and the support 10. Conversely, the formation of the stack composite 50, for example, is preferably also performed by the positioning device 60. At this stage, for example, registration marks 80 applied to the sub-stencils 50.1, 50.2, 50.x can be used for their alignment within the stack composite 50. Other known alignment options may also be suitable. Guide elements 70 operatively connected to the sub-stencils 50.1, 50.2, 50.x ensure very precise partial removals of the material geometry 45 from the mold. As a result, once the printing process is completed, solder-paste deposits or adhesive deposits 26 have been printed on the outer pads 25 of the carrier substrate 20. A plurality of associated solder-paste or adhesive deposits are implemented in the form of a pattern arrangement, which corresponds in particular to the connection diagram of an electrical and/or electronic component to be electrically connected to the carrier substrate 20. By placing the electrical and/or electronic component on the solder-paste deposits or adhesive deposits in a further production step, for example, in the case of solder-paste deposits by a re-flow process, a materially bonded connection to the carrier substrate 20 can be implemented.

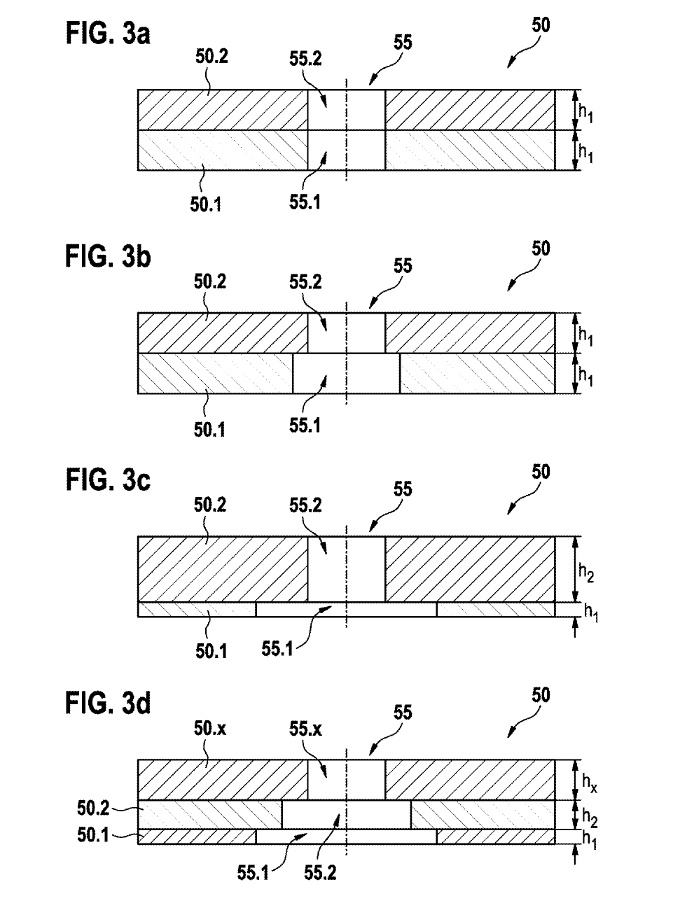

In FIGS. 3a) to 3d), different designs of a stack composite 50 of sub-stencils 50.1, 50.2, 50.x are shown. Common to all of them is the fact that an opening 55 in the stack composite 50 represents a particular material geometry 45 to be printed. In FIGS. 3a) to 3c), the stack composite 50 comprises in each case two sub-stencils 50.1, 50.2, while in FIG. 3d) more than two sub-stencils 50.1, 50.2, 50.x (as an example, 3 sub-stencils shown) are also used. In FIG. 3a) the sub-stencils 50.1, 50.2 are identical. This allows a material geometry 45 with a constant cross section to be printed. In FIG. 3b), the sub-stencils 50.1, 50.2 each have the same stencil thickness h1. However, the partial openings 55.1, 55.2 contained in the sub-stencils 50.1, 50.2 differ in their cross-sectional shape and/or size. This allows material geometries with varying cross-sectional area to be printed, such as stepped cylinders. The same applies to the stack composite 50 according to FIG. 3c), wherein here, however, the sub-stencils 50.1, 50.2 have different stencil thicknesses h1, h2. The definition of the stencil thicknesses h1, h2, for example, can be based on the modified cross-sectional areas or a maximum possible shaping area of the individual sub-stencils 50.1, 50.2. FIG. 3d) shows a multiplicity of sub-stencils 50.1, 50.2, 50.x within a stack composite 50. The sub-stencils 50.1, 50.2, 50.x differ in their stencil thicknesses h1, h2, hx and in the different designs of their partial openings 55.1, 55.2, 55.x. Many other designs of stack composites 50 are possible, which are produced, for example, from a partial combination of two or more sub-aspects of the designs of stack composites 50 shown in FIG. 3a) to d).

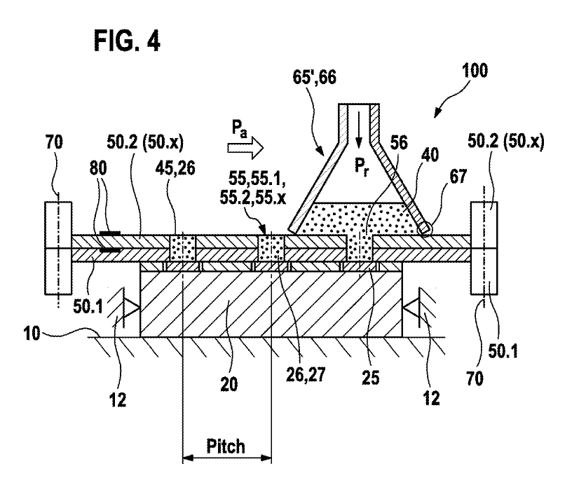

FIG. 4 shows an alternative method of introducing the viscous or pasty print material 40 into the openings 55 of the stack composite 50 by means of an excess pressure blade 65′. This comprises, for example, a storage chamber 66 with the print material 40 contained therein. The storage chamber 66 is also implemented, for example, as a printing head, which rests on the stencil or the uppermost sub-stencil 50.x of the stack composite 50 during the insertion of the print material 40. The printing head covers at least one entry opening surface 56 of the stencil, facing away from the carrier substrate 20. The print head is designed to introduce the print material 40 into the at least one opening 55. The print material 40 is forced out of the storage chamber 66 using a feeder device (not shown) and introduced into the opening 55 with an excess pressure Pr. The excess pressure Pr is accordingly elevated, in particular compared to an external pressure Pa present outside the storage chamber 66, for example the atmospheric pressure. The print material 40 introduced into the opening 55 is finally leveled off by the blade 67 arranged externally on the storage chamber 66. FIG. 4 shows the excess pressure blade 65′ at a time during a printing process which corresponds to that in FIG. 1c. In addition, the center-to-center distance (pitch) of two immediately adjacent openings 55 is shown. Finally, a plurality of material deposits 26 are printed on the carrier substrate 20 at a respective pitch spacing relative to each other in the form of a pattern arrangement 27.

1. A printing device (100) for applying a viscous or pasty material (40) onto a carrier substrate (20) and shaping a defined material geometry (45) by means of a stencil, wherein the stencil has at least one continuous opening (55) with an application opening surface (50.1c) facing the carrier substrate (20) and the inner wall of the opening (55) forms an outer boundary for an outer surface (46) of the material geometry (45) to be shaped, wherein the stencil is configured to overcome an adhesive force of the viscous or pasty material (40) acting on the inner wall of the opening (55) by means of a relative movement,
characterized in that
the stencil is formed as a stack composite (50) of at least two sub-stencils (50.1, 50.2, 50.x) adjoining each other in a connection region (30), wherein the sub-stencils (50.1, 50.2, 50.x) each have at least one partial opening (55.1, 55.2, 55.x), by means of which the inner wall of the opening (55) is divided into proportional shaping areas (50.1a, 50.2a, 50.xa) of the sub-stencils (50.1, 50.2, 50.x), and wherein connection surfaces (50.1a, 50.1b) of the sub-openings (55.1, 55.2, 55.x) which correspond to one another are formed in the connection region (30), and the sub-stencils (50.1, 50.2, 50.x) can each be reversibly separated from one another in the connection region (30).

2. The printing device (100) as claimed in claim 1, characterized in that for the stencil (50) an overall area ratio as the ratio of the area of the inner wall to the application opening surface (50.1c) is =<0.66.

3. The printing device (100) as claimed in claim 1, characterized in that for a sub-stencil (50.1, 50.2, 50.x) a part-related area ratio as the ratio of the shaping area (55.1a, 50.2a, 55.xa) of the partial opening (55.1, 55.2, 55.x) to the connection surface area (50.1b, 50.2b) or to the application opening surface (50.1c) is >=0.66.

4. The printing device (100) as claimed in claim 1, characterized in that for the stencil (50) an overall aspect ratio as the ratio of the smallest opening width of the opening (55) to the stencil thickness (h) of the stencil (50) is <1.5.

5. The printing device (100) as claimed in claim 1, characterized in that the printing device (100) has a closed excess pressure blade (65′) for applying the viscous or pasty material (40) into the at least one continuous opening (55) of the stencil, wherein the closed excess pressure blade (65′) is formed by a printing head, which rests on the stencil and completely covers an entry opening surface (56) of the stencil facing away from the carrier substrate (20) and which is configured to introduce the viscous or pasty material (40) into the opening (55) under pressure.

6. The printing device (100) as claimed in claim 1, characterized in that at least two partial openings (55.1, 55.2, 55.x) of a sub-stencil (50.1, 50.2, 50.x) or the partial openings (55.1, 55.2, 55.x) of at least two sub-stencils (50.1, 50.2, 50.x) in the stack composite (50) which form the at least one opening (55) are configured differently in geometry and/or size.

7. The printing device (100) as claimed in claim 1, characterized in that the stencil (50) comprises a plurality of openings (55), wherein a center-to-center distance (pitch) of two immediately adjacent openings (55) is <=2 mm.

8. A printing method for applying a viscous or pasty material (40) onto a carrier substrate (20) and for shaping a defined material geometry (45) using a stencil, wherein the stencil has at least one continuous opening (55) with an application opening surface (50.1c) facing the carrier substrate (20) and the inner wall of the opening (55) forms an outer boundary for the outer surface (46) of the material geometry (45) to be shaped, the method comprising
determining a maximum shaping area (50.1a, 50.2a, 50.xa) of the stencil for a circumferential outer surface section (46.1, 46.2, 46.x) of the material geometry (45), at which an adhesive force of the viscous or pasty material (40) acting on the shaping area (50.1a, 50.2a, 50.xa) can still be overcome under a relative movement of the stencil, and
at delayed intervals, beginning the removal of at least two outer surface sections (46.1, 46.2, 46.x) of the material geometry (45) from the mold, in each case having a surface area up to the size of the specified shaping area (50.1a, 50.2a, 50xa), by means of the stencil.

9. The printing method as claimed in claim 8, characterized in that at least one of the outer surface sections (46.1, 46.2, 46.x) having an area up to the size of the specified maximum shaping area (50.1a, 50.2a, 50.xa) is completely demolded before the removal of at least one other outer surface section from the mold is begun.

10. The printing method as claimed in claim 8, characterized in that after a sub-region of at least one outer surface section (46.1, 46.2, 46.x) has already been removed from the mold, at least one other outer surface region is then removed from the mold at the same time, wherein the simultaneous demolding is executed in such a way that at any subsequent time a surface area of the remaining areas of these outer surface sections yet to be demolded is present, which is smaller than the specified maximum shaping area.

11. The printing method as claimed in claim 8, characterized in that the viscous or pasty material (40) is formed as a material deposit (26) on a bonding pad (25) on a circuit substrate (20).

12. The printing method as claimed in claim 8, characterized in that a solder paste, a thermal conducting paste, a conductive paste or a conductive adhesive is printed onto the carrier substrate (20) as the viscous or pasty material (40).

13. A circuit substrate (20) having at least one material deposit (26) applied by means of stencil printing and with a defined material geometry (45), wherein
the at least one imprinted material deposit (26) has a printable surface connecting to the carrier substrate (20) and the material geometry (45) has an outer surface (46) shaped by means of an inner wall of an opening (55) of the printing stencil (50), wherein a ratio of the outer surface (46) to the printable surface is <0.66.

14. The circuit substrate (20) as claimed in claim 13, characterized in that the imprinted material deposit (26) has different cross-sectional areas and/or shapes in cutting planes parallel to the printable surface.

15. The circuit substrate (20) as claimed in claim 13, having a plurality of material deposits (26) in the form of a pattern arrangement (27).

16. The printing device (100) as claimed in claim 1, wherein the relative movement is a movement relative to the carrier substrate (20).

17. The printing device (100) as claimed in claim 1, characterized in that for the stencil (50) an overall area ratio as the ratio of the area of the inner wall to the application opening surface (50.1c) is 0.3 to 0.5.

18. The printing device (100) as claimed in claim 1, characterized in that for a sub-stencil (50.1, 50.2, 50.x) a part-related area ratio as the ratio of the shaping area (55.1a, 50.2a, 55.xa) of the partial opening (55.1, 55.2, 55.x) to the connection surface area (50.1b, 50.2b) or to the application opening surface (50.1c) is 0.66 to 2.

19. The printing device (100) as claimed in claim 1, characterized in that for the stencil (50) an overall aspect ratio as the ratio of the smallest opening width of the opening (55) to the stencil thickness (h) of the stencil (50) is 0.6 to 1.0.

20. The printing device (100) as claimed in claim 1, characterized in that the stencil (50) comprises a plurality of openings (55) in a pattern arrangement (27), wherein a center-to-center distance (pitch) of two immediately adjacent openings (55) is <=0.5 mm.

21. The method as claimed in claim 8, wherein the relative movement is a movement relative to the carrier substrate (20).

22. The printing method as claimed in claim 8, characterized in that the viscous or pasty material (40) is formed as a material deposit (26) on a bonding pad (25) on a circuit substrate (20), and in the form of a printed circuit board, a DBC, an LTCC, an IMC, a wafer or a solar cell, with the defined material geometry (45).

23. The circuit substrate (20) as claimed in claim 13, wherein the at least one imprinted material deposit (26) is a solder paste or an adhesive deposit (26)
